(19) United States
(12) Patent Application Publication
(10) Pub. No.: US 2009/0245307 A1
(43) Pub. Date: Oct. 1, 2009

(54) LASER FORMING APPARATUS AND METHOD FOR MANUFACTURING HEAD SUSPENSION WITH THE APPARATUS

(75) Inventors: Susumu IIDA, Kawasaki (JP); Naohisa MATSUSHITA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/364,244

(22) Filed: Feb. 2, 2009

(30) Foreign Application Priority Data
Mar. 27, 2008 (JP) 2008-084640

(51) Int. Cl. H01S 3/08; H01L 21/00

(52) U.S. Cl. 372/29.014; 438/29; 257/E21.002

(57) ABSTRACT

In a laser forming apparatus, a first optical system and a second optical system are provided symmetrically with respect to a vertical plane to a center line of a head suspension targeted for spring pressure adjustment. A half mirror branches laser light emitted from one laser oscillator into two to guide the branched light beams to the two optical systems. The head suspension is structured such that optical spots formed by the first and second optical systems condensing laser light are positioned at the same distance from the center line of the head suspension. Condenser lenses of the first and second optical systems are arranged on right and left sides in a plane-symmetrical form to scan the optical sports to thereby adjust a spring pressure of a head suspension.

### BACKGROUND

1. Field

The present technique relates to a laser forming apparatus, and a method for manufacturing a head suspension using the apparatus. In particular, the present technique relates to a laser forming apparatus capable of adjusting a spring pressure of a spring member made of thin-sheet metal with a laser beam, and a method for manufacturing a head suspension using the apparatus.

2. Description of the Related Art

A magnetic head suspension (hereinafter simply referred to as “head suspension”) is a precision spring member constituting a magnetic disk device. A so-called head slider provided with a magnetic head for writing/reading data is mounted to a tip end of the magnetic head suspension, and its read end is attached to a tip end of an oscillating air that is oscillated by a VCM (voice coil motor). The head suspension is manufactured generally based on press molding, by using a stainless steel thin plate having a thickness of about 20 to 30 μm.

This head suspension has a spring function, which balances with a floating force of an air bearing suspension (ABS) provided on one surface of the head slider opposite to a magnetic recording medium and floats the head slider by a predetermined height on the magnetic recording medium. In response to a demand for a small-size/large-recording-capacity magnetic disk device, the head suspension is required to realize a floating amount of 10 nm or less. Further, an extremely high spring pressure accuracy has been required of the head suspension in accordance with such a request.

To that end, various methods for adjusting a spring pressure of a head suspension have been proposed. To give an example thereof, there is a method utilizing a laser forming technique. The laser forming technique is a processing technique for applying a concentrated laser beam to a metal thin plate and scanning the plate with the beam to generate a temperature gradient of the metal material in a plate thickness direction with a thermal energy of the laser beam to plastically deform the metal thin plate utilizing the temperature gradient. Further, the laser forming technique has a feature that high-accuracy formation can be performed without causing a target component to spring back, and the bending angle can be finely controlled only by adjusting a laser scanning condition in addition to a feature that a forming process can be performed in a non-contact manner. Therefore, the laser forming technique expands its application as a promising technique of adjusting a spring pressure of a head suspension. In order to stably maintain a floating amount of the head slider from the magnetic recording medium, how to avoid torsional deformation of the head suspension is important. Employed as a measure for avoiding torsional deformation of the head suspension is the structure in which the head suspension has a symmetrically shape, an opening is formed at the center for size reduction, and both sides of the head suspension are given a spring function.

Here, as described above, the head slider is mounted at the tip end of the head suspension, and a processing circuit for processing a read/write signal of the magnetic head is provided outside the oscillating arm. Thus, it is necessary to provide an electric circuit for transmitting an electric single between the magnetic head and the processing circuit on the surface of the head suspension.

To avoid the torsional deformation of the head suspension, employed is the structure in which the electric circuit is provided at the center of the head suspension. Therefore, the recent trend of the magnetic head suspension shape is such that an opening formed near the base portion close to the rotational axis of the head suspension is divided by the electric circuit. The widths of beams that realize a spring function at both sides, the width of the opening divided into two across the electric circuit, and the width of the electric circuit portion are set to as a small value as about 0.5 mm or less.

In the case of adjusting a spring pressure of the thus-structured head suspension based on the laser forming techniques, one laser light is applied to a spring formation portion along one straight line in the horizontal direction to the head suspension or along plural straight lines in the horizontal directions to thereby adjust a spring pressure.

However, if the above method is applied to adjustment of the spring pressure of the head suspension structured as above, the following problem arises.

(1) To prevent the electric circuit portion formed at the center of the suspension from being irradiated with laser light and damaged, it is necessary to adopt (a) a method for preventing the electric circuit portion from being irradiated with laser light by covering the electric circuit with a light-shielding mask not to irradiate the circuit with laser light or (b) a method for preventing the electric circuit portion from being irradiated with laser light through on/off control on laser light (electrical control over laser oscillator's on/off states or on/off control on a mechanical shutter).

However, the method (a) is advantageous in that laser on/off control can be omitted but is disadvantageous in that a light-shielding mask conforming to the shape of a target member should be prepared, and a step of setting a light-shielding mask is added. Further, as for the method (b), high-speed on/off control on laser light is required, and if the width of the electric circuit portion is narrow with respect to the laser light scanning speed, such control could not be performed.

(2) Since the laser forming technique is a plastic deformation process utilizing a temperature gradient generated in the plate thickness direction, a temperature rise of a material itself, which results from the continuous laser light irradiation, causes a decrease in bending deformation amount. This phenomenon suggests that the bending deformation degree differs between the start point and end point of laser scanning. In the case of scanning laser light in one direction, a target member sustains torsional deformation. This tendency is more pronounced if a material to be processed has a smaller size. Thus, this method is inappropriate for adjustment of a spring pressure of a member weak to torsional deformation, such as the head suspension.

Proposed as a measure for preventing such torsional deformation is a method for scanning laser light to and fro. Even this method involves deformation twice change in spring pressure, which is adjustable through one laser scanning, resulting in a problem of requiring a resolving power twice that in one-directional scanning.

(3) Further, as another measure for solving the above problem, there is a method for irradiating left and right spring portions of the head suspension separately; for example, spring structure portions are scanned with laser light in opposite directions sequentially such that the left spring portion is scanned with the laser light leftward from the edge of the left opening and then, the right spring portion is scanned with the laser light rightward from the edge of the right opening. With this method, torsion stress is applied to the left and right spring portions in opposite directions. Therefore, torsion-free adjustment is realized in the entire head suspension.

However, even this method requires an operation of scanning one head suspension with the laser light in two or more steps, resulting in a problem of increasing a processing time per head suspension about two-fold.

Hereinafter, the related art will be described in detail with reference to accompanying drawings.

FIG. 1A shows the structure of a laser forming apparatus 90 provided with a spring pressure adjustment jig 32 used for a conventional spring pressure adjusting method using laser light. A fixed end 3 of a cantilevered spring member 1 is set on a mounting block 29 of the spring pressure adjustment jig 32, and a head slider 5 provided with a magnetic head attached to a head supporting end 2 of the spring member 1 is placed on a strain gauge 10. Paired irradiation units 7 and 8 are arranged on upper and lower sides of the spring member 1 face to face across the spring member 1. The irradiation units 7 and 8 are connected to an irradiation unit driving unit 11 through an arm 19 and moved orthogonally to a length direction of the spring member 1 by means of the irradiation unit driving unit 11.

A laser irradiating apparatus includes a laser light oscillator 13, a light control unit 14, and the irradiation units 7 and 8 with a built-in condenser lens connected through an optical cable 6. The light control unit 14 includes a half mirror 16 and a mirror 17, which serve to guide laser light oscillated with the laser light oscillator 13 to front and rear sides, shutter mechanisms 9, 9′ that allow/disallow transmission of light reflected by the mirrors 16 and 17, and a shutter opening/closing control unit 18.

Laser light reflected by the half mirror 16 reaches the irradiation unit 7 through the shutter mechanism 9 and the optical cable 6. Then, the light is condensed and emitted to form an optical spot 4 on the front side of the spring member 1. On the other hand, laser light, which passed through the half mirror 16 and was reflected by the mirror 17, reaches the connected irradiation unit 8 through the shutter mechanism 9 and the optical cable 6. Then, the light is condensed and emitted to form an optical spot 4′ on the rear side of the spring member 1.

In this way, the optical spots 4, 4′ are switchably formed on the front and rear sides of the spring member 1 in accordance with a result of determining whether a pressure level (indicated by an output indicator 31), which is detected by the strain gauge 10 as a spring pressure sensor, is high or low; the determination is performed with a spring pressure detection control unit 12. More specifically, a shutter opening/closing driving unit 18 in the light control unit 14 carries out the above operation. To describe how the shutter opening/closing driving unit 18 opens/closes the shutter mechanisms 9, 9′, the shutter opening/closing driving unit 18 controls opening/closing operations such that if one of the shutter mechanisms 9, 9′ is opened, the other one is closed.

The spring pressure detection control unit 12 stores a reference pressure value of the spring member 1 in advance. Further, the maximum allowable value that is larger than the reference pressure value and the minimum allowable value that is smaller than the reference pressure value are set for pressure adjustment. The spring pressure detection control unit 12 incorporates a comparator for comparing the maximum allowable value and the minimum allowable value with a pressure detected with the strain gauge 10. If the pressure detected with the strain gauge 10 is within the maximum allowable value range and the minimum allowable value range, spring pressure adjustment is completed. However, if the pressure detected with the strain gauge 10 is above the maximum allowable value, the spring pressure detection control unit 12 sends a signal to the shutter opening/closing driving unit 18 to open the shutter mechanism 9 and close the shutter mechanism 9′. Thus, the irradiation unit 7 emits light to form the optical spot 4 to thereby lower a spring pressure.

On the other hand, if the pressure detected with the strain gauge 10 is below the maximum allowable value, the spring pressure detection control unit 12 sends a signal to the shutter opening/closing driving unit 18 to open the shutter mechanism 9′ and close the shutter mechanism 9. Thus, the irradiation unit 8 emits light to form the optical spot 4′ to thereby increase a spring pressure. The drive signal for opening/closing the shutter is also sent to the irradiation unit driving unit 11 to scan the optical spots 4, 4′ to and fro between spring ends in a width direction of the spring member 1.

FIG. 1B shows the detailed structure of the spring member 1 of FIG. 1A, which is used as a head suspension.

The head slider 5 provided with a magnetic head is attached to the head supporting end 2 as the tip end of the head suspension 1. Further, an opening 21 is formed at the proximal end side close to the fixed end 3 of the head suspension 1, and an electric circuit 20 connected to the head slider 5 is set on the head suspension 1 with the opening being divided into two in a width direction. A supporting member 22 for attaching the spring member 1 to an oscillating arm (not shown) is provided on the fixed end 3 side of the spring member 1. The electric circuit 20 has a width W1 of about 1 mm, the opening 21 has a width W2 of about 2 mm, and a width W3 from the edge of the opening 21 to the edge of the head suspension 1 is about 0.5 mm.

If the laser forming apparatus 90 of FIG. 1A performs laser forming on the head suspension 1 of FIG. 1B, the electric circuit 20 overlaps a laser scanning line S of the head suspension 1 as shown in FIG. 2A. Therefore, a light-shielding mask 23 is put on the electric circuit 20 to prevent the electric circuit 20 from being irradiated with laser light and damaged. In this way, the electric circuit 20 is prevented from being irradiated with laser light L user upon laser forming. However, the method illustrated in FIG. 2A has an advantage that on/off control on the laser light L can be omitted but has a problem that the light-shielding mask 23 should be prepared so as to conform to the shape of the electric circuit 20 and an additional step of setting the light-shielding mask 23 should be executed at every laser forming operation.

To overcome the problem, proposed is a method for preventing the electric circuit 20 from being irradiated with the laser light L through on/off control on the laser light L (electrical on/off control of the laser light oscillator 13 or on/off control on the shutter mechanisms 9, 9′) as shown in FIG. 2B. However, according to the method illustrated in FIG. 2B, it is important to execute on/off control at a high speed, resulting in such a problem that the control could not be executed if the width of the electric circuit 20 is small relative to a scanning speed of the laser light L.

Since the laser forming technique is a plastic deforming process based on a temperature gradient generated in the plate thickness direction of the spring member 1, a bending deformation amount is lowered due to a temperature rise of a material accompanying continuous laser irradiation. This phenomenon suggests that the bending deformation degree differs between the start point and end point of laser scanning. In the case of scanning the laser light L in one direction as shown in FIG. 3A based on the method illustrated in FIG. 2A or 2B, the head suspension 1 member sustains torsional deformation as shown in FIG. 3B. This tendency is more pronounced if a material to be processed has a smaller size. Thus, this method is inappropriate for adjustment of a spring pressure of a member weak to torsional deformation, such as the head suspension 1.

To give a method proposed for preventing the torsional deformation, as shown in FIG. 4A, in the method illustrated in FIG. 2A, an object is scanned with the laser light L to and fro. Alternatively, as shown in FIG. 4B, in the method illustrated in FIG. 2B, an object is scanned with the laser light L to and fro. However, these methods involve deformation twice change in spring pressure, which is adjustable through one laser scanning, resulting in a problem of requiring a resolving power twice that in one-directional scanning.

Further, as another method for solving the above problem, left and right spring portions 1L and 1R of the spring member 1 are separately irradiated with laser light. According to this method, the left spring portion 1L is scanned with the laser light L leftward from the edge of the left half of the opening 21 on the electric circuit 20 side. After the completion of applying the light leftward, laser is returned to the start position without applying the laser light. Next, the right spring portion 1R is scanned with the laser light L rightward from the edge of the right half of the opening 21 on the electric circuit 20 side. After the completion of applying the light leftward, laser is returned to the start position without applying the laser light. With this method, torsion stress is applied to the left and right spring portions 1L and 1R in opposite directions. Therefore, torsion-free adjustment is realized in the entire head suspension 1.

However, even this method requires an operation of scanning one head suspension 1 with the laser light L in two or more steps, resulting in a problem of increasing a processing time per head suspension about two-fold.

### SUMMARY

It is an object of the subject application to provide a laser forming apparatus, which can adjust a spring pressure of a suspension based on a laser forming technique with a resolving power that enables fine adjustment in a short time without torsional deformation.

According to first aspect of an embodiment, a laser forming apparatus includes: a laser oscillator for emitting laser light, a half mirror for reflecting/transmitting laser light emitted from the laser oscillator, a first optical system for concentrating first laser light reflected by the half mirror with a first condenser lens and guiding an irradiation point of the first laser light to a predetermined position on a spring member placed on a jig, a mirror for reflecting second laser light transmitted through the half mirror, a second optical system for concentrating the reflected second laser light guided in parallel to the first laser light with a second condenser lens, and guiding an irradiation point of the second laser light to a position symmetrical to the predetermined position with respect to a center line of the spring member, and a condenser lens moving mechanism for moving the first condenser lens and the second condenser lens to scan the two irradiation points in a direction vertical to the center line of the spring member.

### BRIEF DESCRIPTION OF THE DRAWINGS

FIG. 1A is a diagram showing the structure of a spring pressure adjustment jig used in a conventional spring pressure adjustment method utilizing laser light, and FIG. 1B schematically shows the structure of a spring member of FIG. 1A;

FIG. 2A illustrates a first example of a conventional method for scanning laser light in a head suspension of FIG. 1B, and FIG. 2B illustrates a second example of a conventional method for scanning laser light in a head suspension of FIG. 1B;

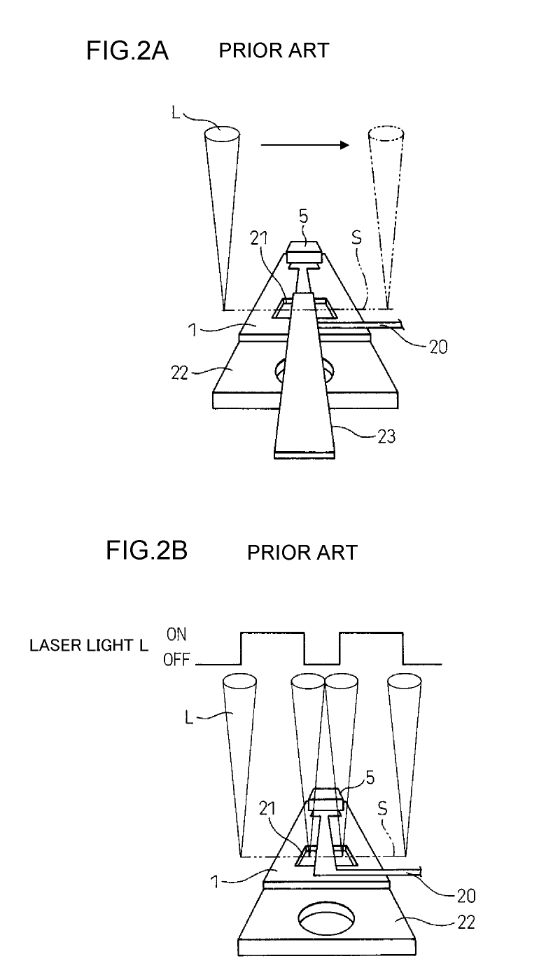

FIG. 3A shows how a head suspension is scanned with laser light in one direction as shown in FIGS. 2A and 2B, and FIG. 3B shows how torsion occurs in the head suspension as a result of scanning laser light in FIG. 3A;

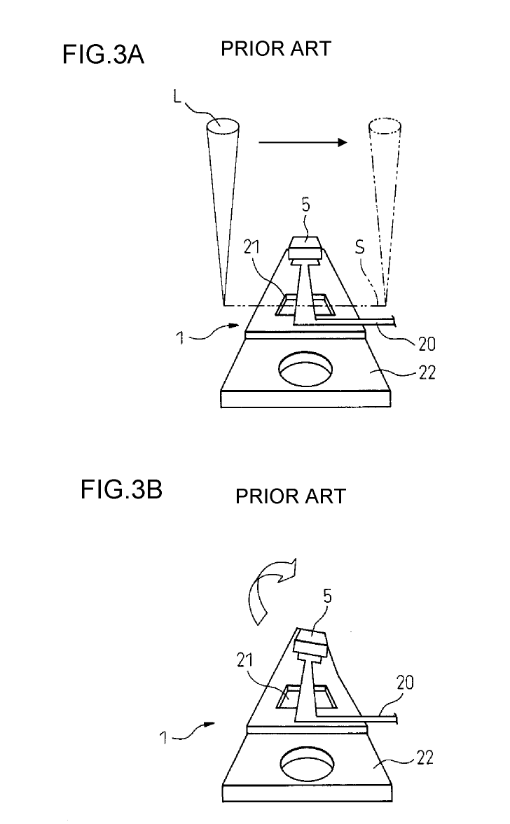

FIG. 4A illustrates a third example of a conventional method for scanning laser light in a head suspension of FIG. 1B, FIG. 4B illustrates a fourth example of a conventional method for scanning laser light in a head suspension of FIG. 1B, and FIG. 4C illustrates a fifth example of a conventional method for scanning laser light in a head suspension of FIG. 1B;

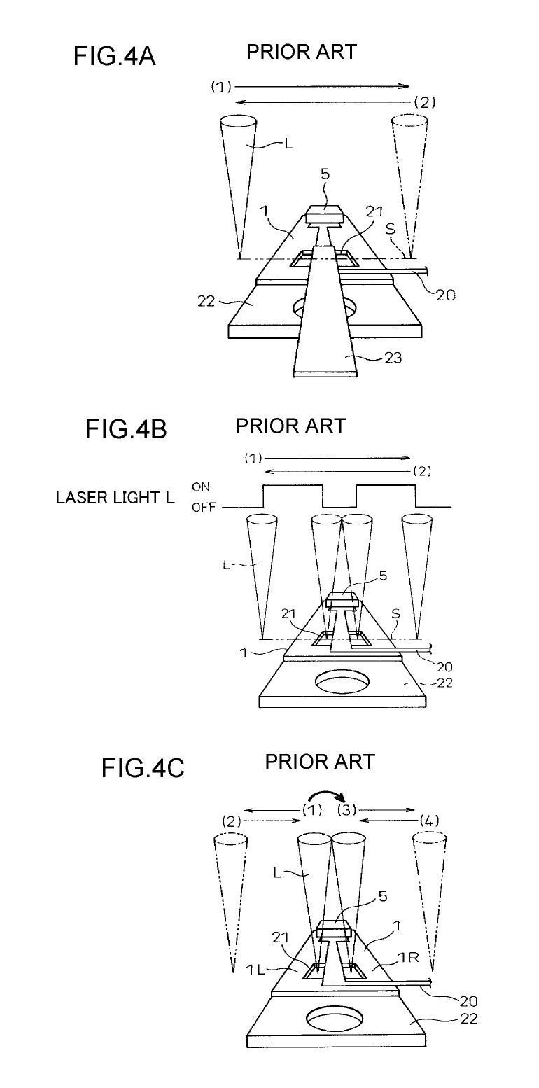

FIG. 5A is a perspective view showing the structure of main components of a laser forming apparatus according to a first embodiment of the subject application, FIG. 5B is a side view of an example of a condenser lens of FIG. 5A, and FIG. 5C illustrates how laser light is scanned in an X-axis direction in the laser forming apparatus of FIG. 5A;

FIG. 6 illustrates how laser light is scanned in a Y-axis direction in the laser forming apparatus of FIG. 5A;

FIG. 7A shows the structure of a first example of a condenser lens moving mechanism in the laser forming apparatus of FIG. 5A, and FIG. 7B shows the structure of a second example of a condenser lens moving mechanism in the laser forming apparatus of FIG. 5A;

FIG. 8A shows the structure of a third example of a condenser lens moving mechanism in the laser forming apparatus of FIG. 5A, and FIG. 8B illustrates how spots are moved along with movement of condenser lenses in FIGS. 5A and 5B and FIG. 6A;

FIG. 9A shows positions of sports when condenser lenses approach each other in FIGS. 5A and 5B and FIG. 6A, and FIG. 9B shows positions of sports when condenser lenses are moved away from each other in FIGS. 5A and 5B and FIG. 6A; and

FIG. 10 is a perspective view showing the structure of main components of a laser forming apparatus according to a second embodiment of the subject application.

### DESCRIPTION OF THE PREFERRED EMBODIMENTS

Hereinafter, embodiments of the subject application will be described in detail with reference to accompanying drawings.

A first embodiment is described below on the assumption that laser light is applied to the head suspension 1 only from above the head suspension 1. A second embodiment is described below on the assumption that the laser light is applied to the head suspension 1 from above or below the head suspension 1. The laser light is not applied to both sides of the head suspension 1 at the same time but applied to either the upper or lower side.

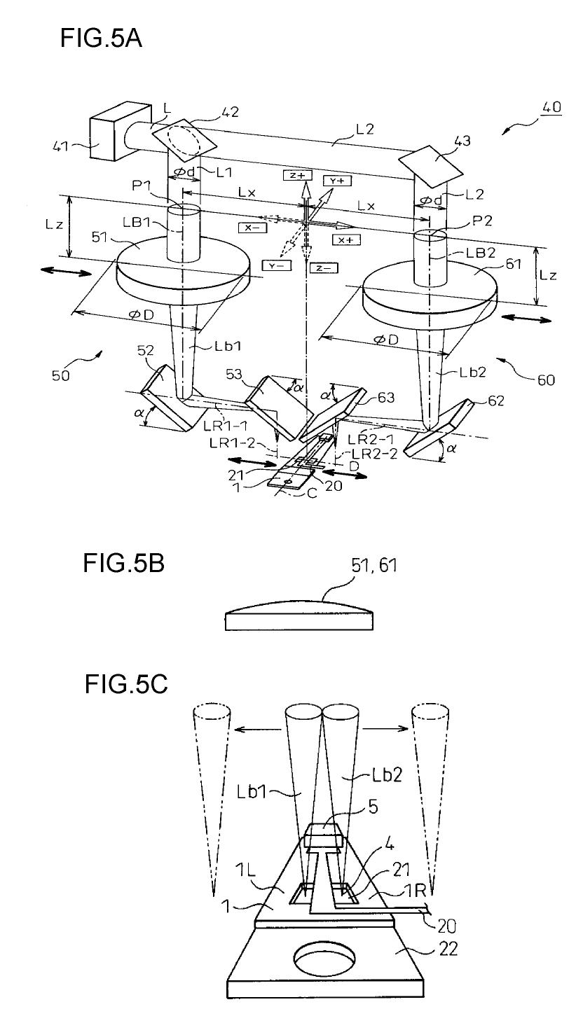

FIG. 5A shows the structure of a laser forming apparatus 40 according to the first embodiment based on the above assumption. The laser forming apparatus 40 includes one laser oscillator 41, a half mirror 42 for dividing laser light L emitted from the laser oscillator 41 into two, a mirror 43 for totally reflecting divided laser light L2, and two optical systems, that is, first and second optical systems 50 and 60. Laser light L1 reflected by the half mirror 42 and laser light L2 totally reflected by the mirror 43 have the same energy. Further, in the two optical systems, or the first and second optical systems 50 and 60, optical components of the same focusing property are arranged symmetrically with respect to a plane that divides the spring member 1 into right and left portions, and optical spots (laser light irradiation points) formed on one head suspension 1 have the same energy.

The first optical system 50 includes a condenser lens 51 and two total-reflection mirrors 52 and 53, and the second optical system 60 includes a condenser lens 61 and two total-reflection mirrors 62 and 63. The condenser lenses 51 and 61 have the same focusing property.

In the first optical system 50, the condenser lens 51 concentrates the laser light L1 reflected by the half mirror 42, and the mirror 52 reflects the concentrated laser light Lb1 toward the second optical system 60. Then, the mirror 53 reflects the laser light Lb1 from the mirror 52 toward a direction parallel to the laser light L1 reflected by the half mirror 42.

Likewise, in the second optical system 60, the condenser lens 61 concentrates the laser light L2 reflected by the mirror 43, and the mirror 62 reflects the concentrated laser light Lb2 toward the first optical system 50. Then, the mirror 63 reflects the laser light Lb2 from the mirror 62 toward a direction parallel to the laser light L2 reflected by the mirror 43.

Further, in the illustrated example of FIG. 5A, the condenser lenses 51 and 61 have a disk-like shape but in actuality, have a convex shape as shown in FIG. 5B, for example. Further, in the optical systems 50 and 60, the condenser lenses 51 and 61, the mirrors 52 and 62, and the mirrors 53 and 63 are arranged symmetrically with respect to a vertical plane passing a central line C of the spring member 1 placed on the jig.

The structure of the optical system in FIG. 5A is described in detail below. Here, the perpendicular passing an intersection between the central line C of the spring member 1 placed on the jig and a line D orthogonal to the central line C at the opening 21 is set to a Z-axis, and the Z-axis is set as a center axis; two axes passing two points P1 and P2 and extending in parallel to the Z axis are set as incident laser optical axes LB1 and LB2. The points P1 and P2 are set at a distance Lx as negative/positive value not smaller than the sum of [radiuses of the condenser lenses 51 and 61]+[½ of a laser scanning distance] from a reference point that is a position above the spring member 1 on an X-axis parallel to the line D.

Laser-condensing convex lenses (condenser lenses 51 and 61), the minimum diameter of which equals the sum of [laser optical spot diameter φd]+[laser scanning distance] are placed at the same height Lz with the two optical axes LB1 and LB2 being set as center axes. Further, laser reflection mirrors 52 and 62 arranged with the reflection surfaces being opposite to each other are set at the same height with the same angle α on the two optical axes LB1 and LB2. Optical axes of the laser light reflected by the laser reflection mirrors 52 and 62 are represented by LR1-1 and LR2-1, respectively.

Further, the laser reflection mirrors 53 and 63 are arranged with the opposite surfaces to the reflection surfaces being opposite to each other are set at the same height with the same angle α as the inclination angle of the laser reflection mirrors 52 and 62 on the two optical axes LR1-1 and LR2-12. Then, positions of the spring structure portions of the spring member 1 as a spring-pressure adjustment object are adjusted to laser-focused positions (optical spot positions) on the laser optical axes LR1 and LR2.

To be specific, the mounting angle of the half mirror 42 and the mirror 43 and the inclination angle α of the reflection mirrors 52, 53, 62, and 63 are set to 45°. As a result, the optical axis of the laser light L2 obtained by branching the laser light L emitted from the laser oscillator 41 by the half mirror 42 into two, the laser light L1 and the laser light L2, and reflected by the mirror 43 becomes parallel to the optical axis of the laser light L1 reflected by the half mirror 42. Further, the optical axes LR1-1 and LR2-1 of the laser light reflected by the mirror 52 and 62 extend along the same line and the optical axes LR1-2 and LR2-2 of the laser light reflected by the mirror 53 and 63 extend in parallel to each other.

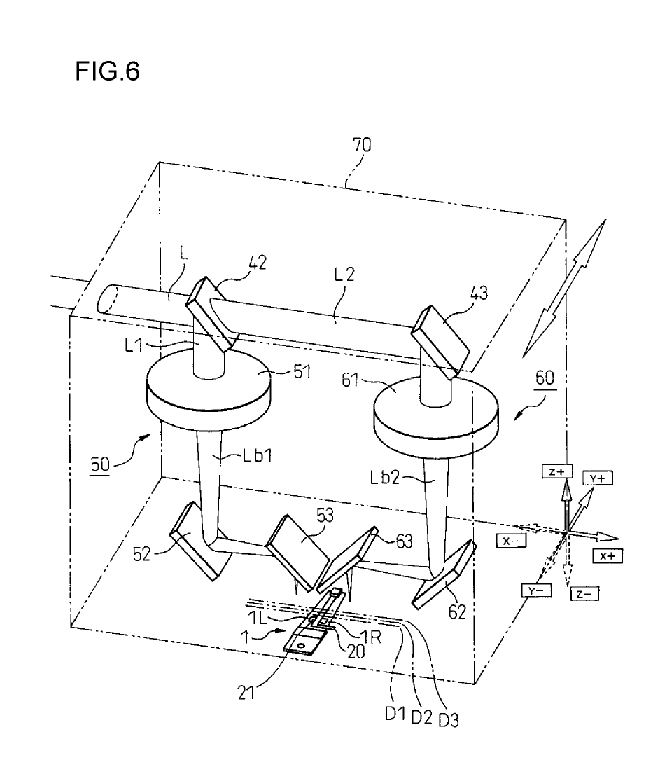

In addition thereto, the laser forming apparatus 40 of this embodiment includes a Y-axis directional moving mechanism 70 that moves the entire optical system composed of the first optical system 50 and the second optical system 60 in the Y-axis direction for positional alignment as shown in FIG. 6. Various mechanisms are conceivable as the Y-axis directional moving mechanism 70 but are not illustrated here. Owing to the Y-axis directional moving mechanism 70, the entire optical system can be moved in the longitudinal direction of the head suspension 1, for example, to positions D1, D2, and D3 as target positions of laser forming.

In the above structure, according to this embodiment, as shown in FIG. 5C, at the positions adjusted with the Y-axis directional moving mechanism 70, the optical spots 4 are moved on the two spring portions 1L and 1R on the both sides, left and right sides, of the opening 21 of the spring member 1 in the opposite directions at the same time. By using such a mechanism as moves the first optical system 50 and the second optical system 60 in the opposite directions, it is possible to move the concentrated laser light beams in the opposite directions at the same time.

However, in the laser forming apparatus 40, a laser irradiation unit and its surroundings have very fine structure. Thus, it is difficult to construct a driving mechanism system that precisely moves the first optical system 50 and the second optical system 60 independently by the same distance to concentrate and scan two laser light beams, unlike the Y-axis directional moving mechanism 70 that moves the entire optical system in the Y-axis direction for positional alignment.

To that end, in this embodiment, provided is an X-axis directional moving mechanism 80 capable of moving the condenser lenses 51 and 61 alone in the first optical system 50 and the second optical system 60 in the opposite directions at the same time. The X-axis directional moving mechanism 80 can move the two condenser lenses, the condenser lenses 51 and 61, in the opposite directions on the X-axis (such that one of the two lenses moves in a positive direction when the other moves in a negative direction) in the same XY-plane.

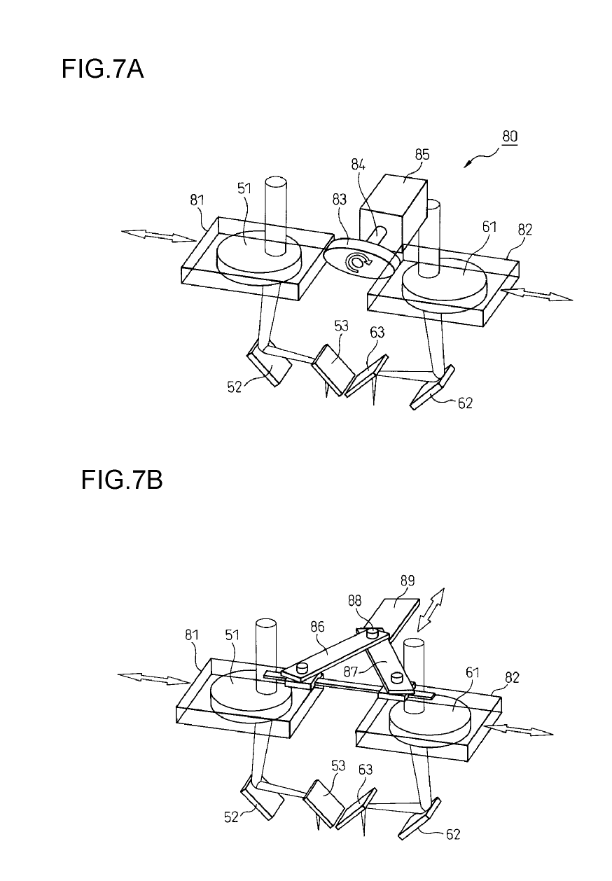

FIG. 7A shows the structure of a first example of the X-axis directional moving mechanism 80. In the first example of the X-axis directional moving mechanism 80, the condenser lens 51 of the first optical system 50 and the condenser lens 61 of the second optical system 60 are accommodated in casings 81 and 82, respectively. The casings 81 and 82 are movable on the same straight line and are biased in the direction of decreasing a distance therebetween, and an elliptical cam 83 is inserted between the casings 81 and 82 with both ends being in contact with the casings 81 and 82. A center shaft 84 of the elliptical cam 83 is revolved by a motor 85. The rotation of the elliptical cam 83 allows the condenser lenses 51 and 61 accommodated in the casings 81 and 82, respectively, to move in opposite directions on the X-axis in the same XY-plane.

FIG. 7B shows the structure of a second example of the X-axis directional moving mechanism 80. Also in the second example of the X-axis directional moving mechanism 80, the condenser lens 51 of the first optical system 50 and the condenser lens 61 of the second optical system 60 are accommodated in casings 81 and 82, respectively. The casings 81 and 82 are movable on the same straight line and one ends of link levers 86 and 87 are rotatably attached to corresponding positions of the casings 81 and 82. The other ends of the link levers 86 and 87 are coupled with a pin 88 and rotatably attached to an operating plate 89. In this way, a link mechanism is completed. The operating plate 89 is connected to a reciprocating mechanism (not shown) and allowed to reciprocate in the Y-axis direction. The reciprocating operation of the operating plate 89 allows the condenser lenses 51 and 61 accommodated in the casings 81 and 82, respectively, to move in opposite directions on the X-axis in the same XY-plane.

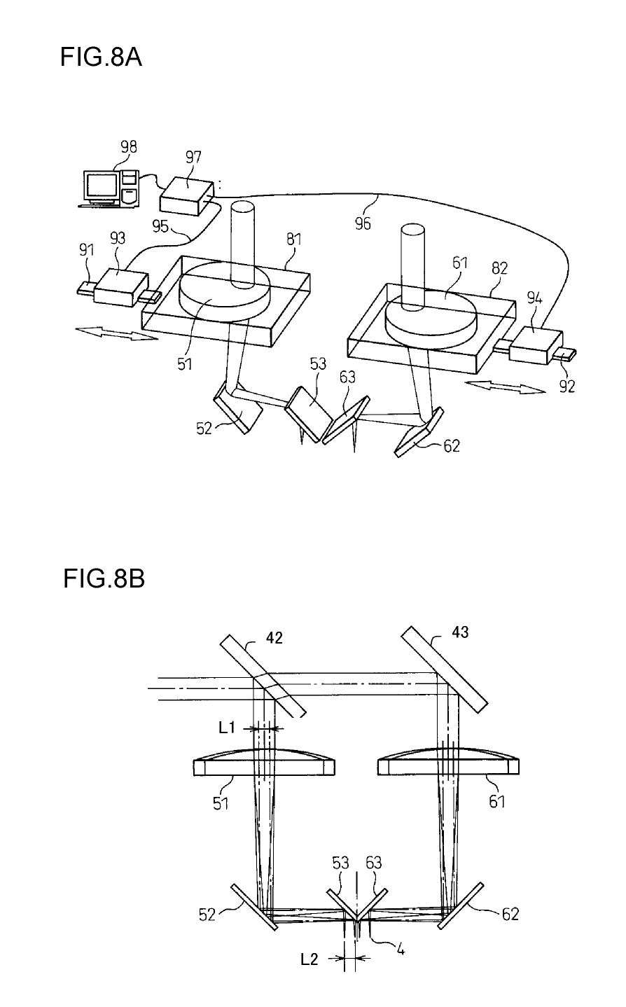

FIG. 8A shows the structure of a third example of the X-axis directional moving mechanism 80. Also in the third example of the X-axis directional moving mechanism 80, the condenser lens 51 of the first optical system 50 and the condenser lens 61 of the second optical system 60 are accommodated in casings 81 and 82, respectively. The casings 81 and 82 are movable on the same straight line and one ends of slide levers 91 and 92 are rotatably attached to corresponding outer positions of the casings 81 and 82. The slide levers 91 and 92 are movable in the X-axis direction with actuators 93 and 94, respectively. The actuators 93 and 94 are connected to a controller 97 through cables 95 and 96, respectively. The controller 97 can be controlled with a computer 98. The reciprocating operations of the slide levers 91 and 92 allow the condenser lenses 51 and 61 accommodated in the casings 81 and 82, respectively, to move in opposite directions on the X-axis in the same XY-plane.

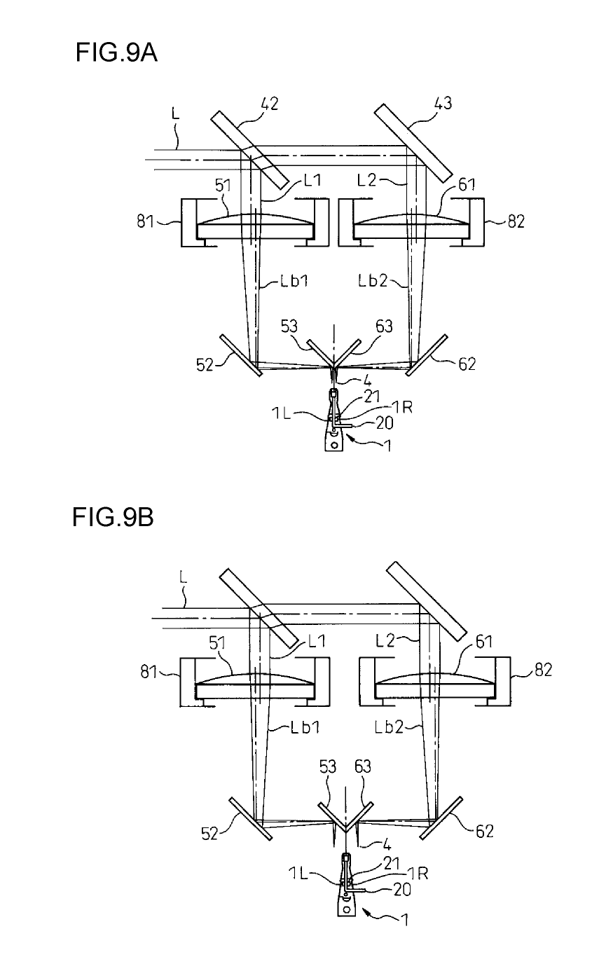

Here, as shown in FIG. 8B, in the first to third examples of the X-axis directional moving mechanism 80, if the condenser lenses 51 and 61 move from the innermost position to the outermost position, the optical spots 4 also move the same distance. For example, if the condenser lenses 51 and 61 move 2.5 mm (refer L1 in FIG. 8B) from the innermost position to the outermost position, the optical spots 4 also move the same distance, 2.5 mm (refer L2 in FIG. 8B). This mechanism is explained with reference to FIGS. 9A and 9B.

FIG. 9A shows a state where the condenser lens 51 accommodated in the casing 81 and the condenser lens 61 accommodated in the casing 82 are at the innermost position. In this state, the optical spots 4 approach each other the most, by the action of the condenser lenses 51 and 61, the mirrors 52 and 62, and the mirrors 53 and 63. The above positions of the optical spots are within the left half and right half of the opening 21 across the electric circuit 20 of the spring member 1, and are at the same distance from the center line of the spring member 1. As the distance between the condenser lenses 51 and 61 increases, the condenser lenses 51 and 61 move the same distance in the same time. Then, the distances of the optical spots 4 of the laser light from the center line similarly increase by the action of the condenser lenses 51 and 61, the mirrors 52 and 62, and the mirrors 53 and 63, and the left and right spring portions 1L and 1R of the spring member 1 are scanned with the optical spots 4.

FIG. 9B shows a state where the condenser lens 51 accommodated in the casing 81 and the condenser lens 61 accommodated in the casing 82 are at the outermost position. In this state, the optical spots 4 are farthest from each other, by the action of the condenser lenses 51 and 61, the mirrors 52 and 62, and the mirrors 53 and 63. The above positions of the optical spots are, for example, outside the left half and right half of the opening 21 across the electric circuit 20 of the spring member 1. Thus, when the optical spots reach these positions, the irradiation of the left and right spring portions 1L and 1R of the spring member 1 is completed. As described above, if the condenser lenses 51 and 61 are moved from the closest positions to the farthest positions, the operation of scanning the optical spots 4 on the left and right spring portions 1L and 1R at both sides of the opening 21 of the spring member 1 is completed.

In this way, in the laser forming apparatus 40 of this embodiment, two optical systems where to reflection mirrors are set on one optical axis to move the laser incident optical axis and the final optical axis in parallel to each other, are prepared and also arranged plane-symmetrically to thereby ensure a certain distance between the two optical axes in the incident portions, which is enough to incorporate various kinds of optical systems or driving systems and further to concurrently apply the laser light to the right and left spring portions formed a little away from each other on both sides of the suspension to be processed.

Further, the two reflection mirrors are arranged on an optical path to the focal point of the condenser lens and the condenser lenses are moved in a horizontal plane, making it possible to concentrate and scan laser light on the spring portions to be processed without changing the height of the focal point. As described above, in the laser forming apparatus 40 of this embodiment, it is possible to ensure a space enough to install the optical system for concentrating laser light or the driving system for scanning laser light and also concurrently concentrate and scan laser light on two portions in the small area to be processed.

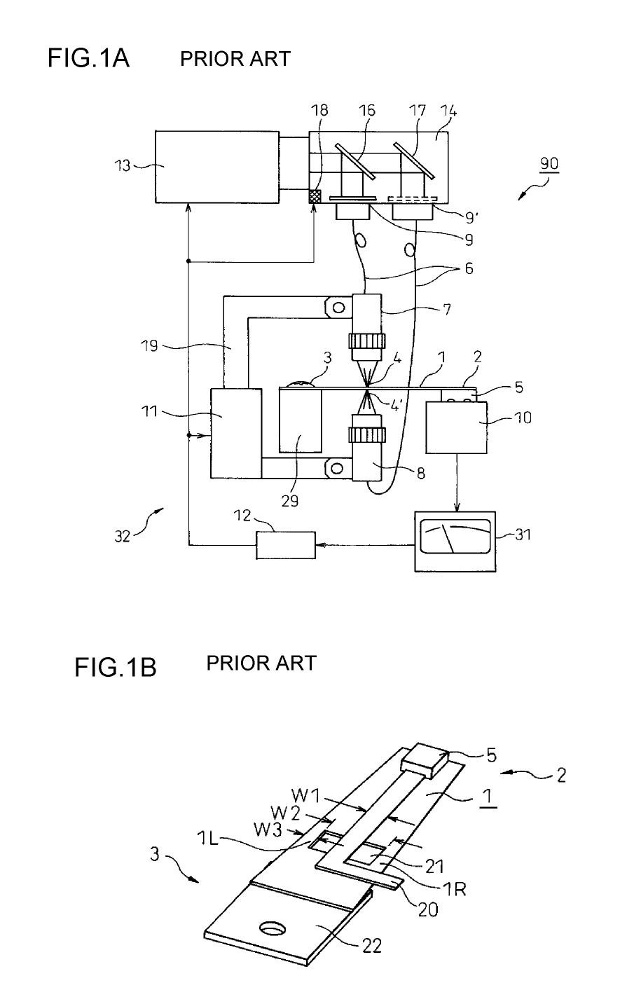

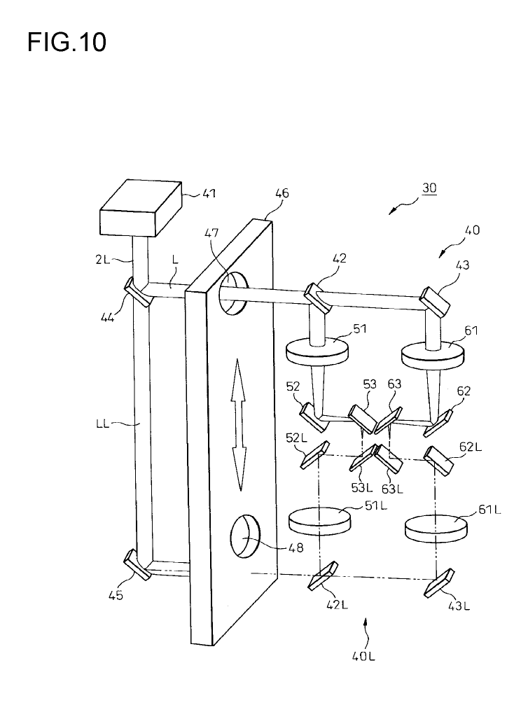

FIG. 10 is a perspective view showing the structure of a laser forming apparatus 30 according to a second embodiment of the subject application. Although the laser forming apparatus 40 can apply the laser light only from above the head suspension 1, the laser forming apparatus 30 can apply the laser light from above and below the head suspension 1 similar to the conventional laser forming apparatus 90 as shown in FIG. 1A.

Therefore, the laser forming apparatus 30 is provided with a laser forming apparatus 40L in addition to the structure of the laser forming apparatus 40; the laser forming apparatus 40L and the laser forming apparatus 40 are arranged symmetrically with respect to the surface on which the spring member 1 is placed. Accordingly, the laser forming apparatus 30 additionally includes the laser forming apparatus 40L provided with a half mirror 42L, a mirror 43L, condenser lenses 51L and 61L, mirrors 52L and 62L, and mirrors 53L and 63L, which are placed at positions corresponding to the half mirror 42, the mirror 43, the condenser lenses 51 and 61, the mirrors 52 and 62, and the mirrors 53 and 63.

In this apparatus, one laser oscillator 41 is provided, and laser light 2L emitted from the laser oscillator 41 is branched into two by the half mirror 44. Laser light L reflected by the half mirror 44 is guided to the half mirror 42 and laser light LL transmitted through the half mirror 44 is guided to the mirror 45 and reflected thereby and then, guided to the half mirror 42L.

On the other hand, a shutter 46 that transmits one of the laser light L and the laser light LL and blocks the other is provided somewhere on an optical path from the half mirror 44 to the half mirror 42 and an optical path from the mirror 45 to the half mirror 42L. The shutter 46 is moved up and down by a driving mechanism (not shown). When an upper window 47 provided in the upper portion of the shutter 46 allows transmission of the laser light L, a lower window 48 provided in the lower portion of the shutter 46 is out of the optical path of the laser light LL, and the laser light LL is blocked by the shutter 46. In contrast thereto, when the lower window 48 allows transmission of the laser light LL, the upper window 47 is out of the optical path of the laser light L, and the laser light L is blocks by the shutter 46.

The laser forming apparatus 30 can deal with an increase/decrease of a spring pressure, which is determined based on a difference between a requisite spring pressure and a measured pressure by switching the upper laser forming apparatus 40 and the lower laser forming apparatus 40L.

The above laser forming apparatus is applicable to spring formation of the head suspension as well as the spring pressure adjustment of the head suspension.

How to adjust a spring pressure of the head suspension 1 with the laser forming apparatus 40 is described next.

First, in step S1, the head suspension is placed on a jig.

Next, in step S2, a spring pressure of the head suspension is measured to determine a requisite adjustment amount of a spring pressure.

Then, in step S3, laser light intensity or irradiation time is determined in accordance with the adjustment amount of the spring pressure.

After that, in step S4, the first and second condenser lenses are adjusted to the closest positions such that optical spots are positioned within the opening.

Next, laser light is emitted from the laser oscillator, and a distance between the first and second condenser lenses is increased with the condenser lens moving mechanism in accordance with the laser light irradiation time.

Then, when the optical spots reach portions outside the head suspension, an operation of the laser oscillator is stopped.

Next, how to adjust a spring pressure of the head suspension 1 with the laser forming apparatus 30 is described.

In step S1, the head suspension is placed on a jig.

In step S2, a spring pressure of the head suspension is measured to determine a requisite adjustment amount of the spring pressure.

In step S3, laser light intensity or irradiation time is determined in accordance with the adjustment amount of the spring pressure, and which one of the upper optical device and the lower optical device is used is determined.

In step S4, in the selected optical device, the first and second condenser lenses are adjusted to the closest positions such that the irradiation point is positioned within the opening.

In step S5, laser light is emitted from the laser oscillator.

In step S6, a distance between the first and second condenser lenses is increased in accordance with the laser light irradiation time with the condenser lens moving mechanism.

In step S7, when the irradiation point reaches a position outside the head suspension, how much the spring pressure is adjusted is determined.

In step S8, if the spring pressure is not adjusted too much, an operation of the laser oscillator is stopped. If the spring pressure is adjusted too much, the remaining optical device is used to repeat the processing in steps S4 to S8.

This technique is that the two laser light beams having the same focusing property with the same energy conditions are used as one pair. And the two spring portions 1L and 1R positioned on the left and right sides of the opening 21 of the head suspension 1 are concurrently scanned with the laser light beams in opposite directions along the same straight line. As a result, the number of laser scanning operations is reduced, and torsional stress is applied to the left and right spring portions 1L and 1R in opposite directions, with the result that torsion-free adjustment is realized in the entire head suspension 1.

Therefore, the laser forming apparatus 30 and the laser forming apparatus 40 and the method for manufacturing a head suspension using the laser forming apparatus according to the subject application attain the following advantages in adjustment of a spring pressure of a head suspension 1 based on laser forming.

(1) Torsion-free spring pressure adjustment is realized.
(2) An adjustment accuracy is twice as high as that of an operation of scanning one laser light to and fro (as for a resolving power, ½).
(3) A spring pressure can be adjusted within ½ or less of a processing time required in a system for scanning one laser light.

What is claimed is:

1. A laser forming apparatus, comprising:
a laser oscillator for emitting laser light;
a half mirror for reflecting/transmitting laser light emitted from the laser oscillator;
a first optical system for concentrating first laser light reflected by the half mirror with a first condenser lens and guiding an irradiation point of the first laser light to a predetermined position on a spring member placed on a jig;
a mirror for reflecting second laser light transmitted through the half mirror;
a second optical system for concentrating the reflected second laser light guided in parallel to the first laser light with a second condenser lens, and guiding an irradiation point of the second laser light to a position symmetrical to the predetermined position with respect to a center line of the spring member; and
a condenser lens moving mechanism for moving the first condenser lens and the second condenser lens to scan the two irradiation points in a direction vertical to the center line of the spring member.

2. The laser forming apparatus according to claim 1, further comprising:
a main optical system for concurrently applying light of the first optical system and light of the second optical system to an area where the first optical system and the second optical system are close to each other.

3. A laser forming apparatus, comprising:
an upper optical device provided on an upper side of a spring member;
a lower optical device provided on a lower side of the spring member;
a laser oscillator for emitting laser light to one of the upper optical device and the lower optical device; and
the upper optical device and the lower optical device each including
a half mirror for reflecting/transmitting laser light emitted from the laser oscillator,
a first optical system for concentrating first laser light reflected by the half mirror with a first condenser lens and guiding an irradiation point of the first laser light to a predetermined position on a spring member placed on a jig,
a mirror for reflecting second laser light transmitted through the half mirror,
a second optical system for concentrating the reflected second laser light guided in parallel to the first laser light with a second condenser lens, and guiding an irradiation point of the second laser light to a position symmetrical to the predetermined position with respect to a center line of the spring member; and
a condenser lens moving mechanism for moving the first condenser lens and the second condenser lens to scan the two irradiation points in a direction vertical to the center line of the spring member.

4. The laser forming apparatus according to claim 1, wherein an optical member in the first optical system and an optical member in the second optical system are arranged symmetrically with respect to a vertical plane passing a center line of the spring member.

5. The laser forming apparatus according to claim 4, wherein the condenser lens moving mechanism moves the first condenser lens and the second condenser lens to increase or decrease a distance from the vertical plane.

6. The laser forming apparatus according to claim 5, wherein the spring member is a head suspension provided with a head at the tip end and an opening at the proximal end, and with an electric circuit that is connected to the head while dividing the opening into right and left portions, and
the condenser lens moving mechanism moves the first condenser lens and the second condenser lens such that the irradiation point is positioned within the opening when the first condenser lens and the second condenser lens are closest to each other, and the irradiation point is positioned outside the head suspension when the first condenser lens and the second condenser lens are farthest from each other.

7. The laser forming apparatus according to claim 1, further comprising:
an optical system moving mechanism capable of integrally moving the first optical system, the second optical system, and the condenser lens moving mechanism toward the center line of the spring member by a predetermined distance.

8. The laser forming apparatus according to claim 1, wherein the condenser lens moving mechanism includes:
separate casings for accommodating the first condenser lens and the second condenser lens;
a biasing mechanism for biasing the casings such that the casings approach each other;
an elliptical cam inserted between the casings;
a rotational shaft attached to a center point of the cam; and
a motor for rotating the rotational shaft.

9. The laser forming apparatus according to claim 1, wherein the condenser lens moving mechanism includes:
separate casings for accommodating the first condenser lens and the second condenser lens;
a moving guide for increasing/decreasing a distance between the casings;
two rods of the same length, one ends of which are rotatably fixed to corresponding positions of the casings with a pin and the other ends of which are coupled together with a connecting pin; and
a reciprocating mechanism for reciprocating the connecting pin in a direction vertical to the moving guide.

10. The laser forming apparatus according to claim 1, wherein the condenser lens moving mechanism includes:
separate casings for accommodating the first condenser lens and the second condenser lens;
a moving guide for increasing/decreasing a distance between the casings;
an actuator capable of independently moving the casings on the moving guide; and
a control circuit for controlling an operation of the actuator such that the two casings are moved by the same distance by the actuator so as to move closer to or away from each other.

11. The laser forming apparatus according to claim 9, wherein the control circuit is a microcomputer.

12. The laser forming apparatus according to claim 1, wherein the first optical system and the second optical system are provided with a first reflection mirror for reflecting laser light beams concentrated with the first condenser lens and the second condenser lens toward a direction in which the laser light beams approach each other, and a second reflection mirror for reflecting the laser light beam reflected by the first reflection mirror and guiding the laser light beam such that the laser light is vertically incident to the spring member.

13. The laser forming apparatus according to claim 12, wherein an inclination angle of each of the first reflection mirror and the second reflection mirror is 45 degrees.

14. The laser forming apparatus according to claim 3, wherein the laser oscillator includes:
a half mirror for reflecting laser light toward one of the upper optical device and the lower optical device as well as transmitting laser light;
a mirror for reflecting laser light transmitted through the half mirror toward the remaining one of the upper optical device and the lower optical device; and
a shutter for blocking one of the laser light reflected by the half mirror and the laser light reflected by the mirror.

15. A method for manufacturing a head suspension with a laser forming apparatus for adjusting a spring pressure of the head suspension, the apparatus including a laser oscillator for emitting laser light, a half mirror for reflecting/transmitting laser light emitted from the laser oscillator, a first optical system for concentrating first laser light reflected by the half mirror with a first condenser lens and guiding an irradiation point of the first laser light to a predetermined position on the head suspension placed on a jig, a mirror for reflecting the second laser light transmitted through the half mirror, a second optical system for concentrating the reflected second laser light guided in parallel to the first laser light with a second condenser lens, and guiding an irradiation point of the second laser light to a position symmetrical to the predetermined position with respect to a center line of the head suspension, and a condenser lens moving mechanism for moving the first condenser lens and the second condenser lens to scan the two irradiation points in a direction vertical to the center line of the head suspension, comprising the steps of:
placing the head suspension on a jig;
measuring a spring pressure of the head suspension to determine a requisite adjustment amount of the spring pressure;
determining laser light intensity or irradiation time in accordance with the adjustment amount of the spring pressure;
adjusting the first condenser lens and the second condenser lens to the closest positions such that the irradiation point is positioned within the opening;
emitting laser light from the laser oscillator;
increasing a distance between the first condenser lens and the second condenser lens with the condenser lens moving mechanism in accordance with the laser light irradiation time; and
stopping an operation of the laser oscillator when the irradiation point reaches a position outside the head suspension.

16. A method for manufacturing a head suspension with a laser forming apparatus for adjusting a spring pressure of the head suspension, the apparatus including an upper optical device provided on an upper side of the head suspension, a lower optical device provided on a lower side of the head suspension, a laser oscillator for emitting laser light to one of the upper optical device and the lower optical device, the upper optical device and the lower optical device each including a laser oscillator for emitting laser light, a half mirror for reflecting/transmitting laser light emitted from the laser oscillator, a first optical system for concentrating first laser light reflected by the half mirror with a first condenser lens and guiding an irradiation point of the first laser light to a predetermined position on the head suspension placed on a jig, a mirror for reflecting the second laser light transmitted through the half mirror, a second optical system for concentrating the reflected second laser light guided in parallel to the first laser light with a second condenser lens, and guiding an irradiation point of the second laser light to a position symmetrical to the predetermined position with respect to a center line of the head suspension, and a condenser lens moving mechanism for moving the first condenser lens and the second condenser lens to scan the two irradiation points in a direction vertical to the center line of the head suspension, comprising the steps of:
placing the head suspension on a jig;
measuring a spring pressure of the head suspension to determine a requisite adjustment amount of the spring pressure;
determining laser light intensity or irradiation time in accordance with the adjustment amount of the spring pressure and which one of the upper optical device and the lower optical device is used;
adjusting the first condenser lens and the second condenser lens to the closest positions such that the irradiation point is positioned within the opening in the selected optical device;
emitting laser light from the laser oscillator;
increasing a distance between the first condenser lens and the second condenser lens with the condenser lens moving mechanism in accordance with the laser light irradiation time;
determining whether a spring pressure is adjusted too much when the irradiation point reaches a position outside the head suspension; and
stopping an operation of the laser oscillator if a spring pressure is not adjusted too much, and repeating the steps using the remaining optical device if a spring pressure is adjusted too much.
